(19) United States
(12) Patent Application Publication
(10) Pub. No.: US 2026/0203456 A1
(43) Pub. Date: Jul. 16, 2026

(54) SIMULATING MANUFACTURE USING ARTIFICIAL INTELLIGENCE WORKFLOW OPTIMIZATIONS

(71) Applicant: International Business Machines Corporation, Armonk, NY (US)

(72) Inventors: Aaron Keith Baughman, Cary, NC (US); Vinod Anandram Valecha, Pune (IN); Jeremy R. Fox, Georgetown, TX (US); Sarbajit Kumar Rakshit, Kolkata (IN); Tushar Agrawal, West Fargo, ND (US)

(21) Appl. No.: 19/016,352

(22) Filed: Jan. 10, 2025

(51) Int. Cl. G06F 30/13; G06F 30/27

(52) U.S. Cl. CPC G06F 30/13; G06F 30/27

(57) ABSTRACT

Mechanisms are provided to optimize the arrangement of an industrial floor for a product manufacture. The mechanisms receive a product specification data structure comprising a specification of a product for manufacture, and extract features of the specification of the product. The mechanisms identify a bill of materials (BOM) and a manufacturing process specification detailing a sequence of manufacturing operations to be performed using the BOM to manufacture the product. The mechanisms execute a plurality of computer model simulations, by one or more machine learning trained artificial intelligence (AI) computer models, of the manufacturing process, based on the BOM and the manufacturing process specification, under a plurality of different arrangements of manufacturing equipment of an industrial floor. The mechanisms select an optimal arrangement of the manufacturing equipment based on results of the execution of the computer model simulations, and generate an output to implement the selected optimal arrangement.

### BACKGROUND

The present application relates generally to a data processing apparatus and method and more specifically to a computing tool and computing tool operations/functionality for simulating manufacture using artificial intelligence workflow optimizations.

Modern manufacturing processes involve a large number of machines and equipment to manufacture complex products. These machines and equipment are arranged into an industrial floor that implements a product pipeline having many stages where the sub-assemblies are formulated from the various materials and parts, and ultimately combined to generate the product. The arranging of the machines/equipment of the industrial floor is an important consideration when determining how the implement a product line for a given product.

### SUMMARY

This Summary is provided to introduce a selection of concepts in a

simplified form that are further described herein in the Detailed Description. This Summary is not intended to identify key factors or essential features of the claimed subject matter, nor is it intended to be used to limit the scope of the claimed subject matter.

In one illustrative embodiment, a method is provided that comprises receiving a product specification data structure comprising a specification of a product for manufacture. The method further comprises processing the product specification data structure to extract features of the specification of the product. Moreover, the method comprises processing the extracted features to identify a bill of materials (BOM) and a manufacturing process specification detailing a sequence of manufacturing operations to be performed using the BOM to manufacture the product. In addition, the method comprises executing a plurality of computer model simulations, by one or more machine learning trained artificial intelligence (AI) computer models, of the manufacturing process, based on the BOM and the manufacturing process specification, under a plurality of different arrangements of manufacturing equipment of an industrial floor. Furthermore, the method comprises selecting an optimal arrangement of the manufacturing equipment based on results of the execution of the plurality of computer model simulations, and generating an output to at least one computing device to implement the selected optimal arrangement of manufacturing equipment on the industrial floor.

In other illustrative embodiments, a computer program product comprising a computer useable or readable medium having a computer readable program is provided. The computer readable program, when executed on a computing device, causes the computing device to perform various ones of, and combinations of, the operations outlined above with regard to the method illustrative embodiment.

In yet another illustrative embodiment, a system/apparatus is provided. The system/apparatus may comprise one or more processors and a memory coupled to the one or more processors. The memory may comprise instructions which, when executed by the one or more processors, cause the one or more processors to perform various ones of, and combinations of, the operations outlined above with regard to the method illustrative embodiment.

These and other features and advantages of the present invention will be described in, or will become apparent to those of ordinary skill in the art in view of, the following detailed description of the example embodiments of the present invention.

### BRIEF DESCRIPTION OF THE DRAWINGS

The invention, as well as a preferred mode of use and further objectives and advantages thereof, will best be understood by reference to the following detailed description of illustrative embodiments when read in conjunction with the accompanying drawings, wherein:

FIG. 1 is an example diagram describing example costs for determining TCO for a manufacturing floor in accordance with one illustrative embodiment;

FIG. 2 is an example diagram of a process flow for simulation of a product manufacturing workflow of an industrial floor in accordance with one illustrative embodiment;

FIG. 3 is an example diagram of an example data entity relationship and data flow diagram for a manufacturing workflow in accordance with one illustrative embodiment;

FIG. 4 is an example diagram of a distributed data processing system environment in which aspects of the illustrative embodiments may be implemented and at least some of the computer code involved in performing the inventive methods may be executed;

FIG. 5 is an example block diagram of the primary operational components of an artificial intelligence (AI) product manufacture workflow simulator in accordance with one illustrative embodiment; and

FIG. 6 is a diagram illustrating a flowchart of an example operation of an AI product manufacture workflow simulator in accordance with one illustrative embodiment.

### DETAILED DESCRIPTION

The illustrative embodiments provide an improved computing tool and improved computing tool operations/functionality for simulating manufacture ameliorations through intelligent workflow modifications. The mechanisms of the illustrative embodiments provide specific computing tools that determine ameliorations that can reduce total cost of ownership for manufacturing equipment. By optimizing the arrangement and configuration of manufacturing equipment, efficiencies may be introduced that will reduce costs of operation of the manufacturing equipment.

With any industrial floor, there can be different types of activities being performed by equipment and human beings, some of which are value added activities and some are non-value-added activities. The value-added activities are those that directly add value towards the completion of the work product such that, without that activity, the work product cannot be completed. Non-value-added activities are those which do not provide a direct value-added effect to the completion of the work product itself, and act as additional cost/time factors. These non-value-added activities may include activities that do not add value but are essential for performance of value-added activities, and may also include activities that are not essential and could be avoided without impacting the completion of the work-product. For example, a value-added activity may be assembling parts to make the product. A non-value-added activity, but an essential activity, may be the cooling of a part after a value-added activity. A non-value-added activity, which is also not essential, may be material movement, as well as other more intangible costs such as energy costs, unavailability costs for materials, and the like.

The types of non-value-added activities depend on relative positions among the equipment on the industrial floor and the activity workflow to manufacture the product. There can be different types of cost associated for different types of value added and non-value-added activities which are also dependent on the relative positions of the machines. Thus, there are different types of activities that are required, and different types of activities which can be avoided or minimized, such as the non-value-added and non-essential costs, e.g., energy costs, material movement costs, resource unavailability costs, and the like.

Total cost of ownership (TCO) is a financial estimate intended to help buyers and owners determine the direct and indirect costs of a product or service. It is a management accounting concept that can be used in full cost accounting or even ecological economics, where TCO further includes social costs. For manufacturing, as TCO is typically compared with doing business across geopolitical boundaries, and includes factors that extend beyond the initial manufacturing cycle time and cost to make parts. TCO includes a variety of cost of doing business including, for example, shipping and re-shipping, opportunity costs, and the like. TCO also considers incentives developed for an alternative approach, such as tax credits, common language, expedited delivery, and customer-oriented supplier visits, among others.

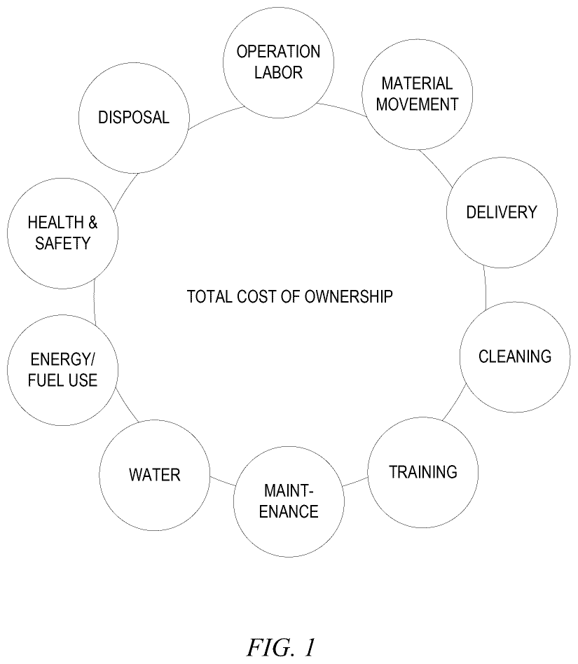

FIG. 1 is an example diagram describing example costs for determining TCO for a manufacturing floor in accordance with one illustrative embodiment. As shown in FIG. 1, TCO comprise a plurality of factors, or costs, that may need to be taken into consideration with regard to the production of a product. These factors may include training of the personnel operating the machinery and equipment for the manufacture of the product, operation labor costs which include salaries and benefits paid to personnel to operate the machinery and equipment, maintenance of the machinery and equipment, water costs for cooling, energy/fuel use costs for powering the machinery/equipment and the many elements of an industrial floor, health and safety costs for ensuring the health and safety of the personnel working on the industrial floor, disposal of waste materials, material movement costs for not only getting materials to the industrial floor but moving the materials from one station to another on the industrial floor, delivery of the manufactured product, and cleaning the machinery/equipment and industrial floor as a whole. Of course, these are only examples of the cost factors involved in determining TCO and many other types of costs may also be included in a model of TCO, as well as a finer grained break down of each of these various factors, without departing from the spirit and scope of the present invention.

As customer demands change day-by-day, and customers are also empowered to customize their products (which may require different processes and/or sequences for manufacturing the customized products), if an optimum workflow or sequence is not utilized, or the relative positions of the machines/equipment are not aligned with the optimum workflow or sequence, then the costs of manufacturing will be increased, e.g., costs of power, material movement, physical resources availability, and the like may all increase. This will increase the aggregated cost of manufacturing, i.e., the TCO of manufacturing. Thus, there is a need for an automated computing tool to simulate the activity and identify how the machines/equipment can be arranged with their relative positions for one or more manufacturing operations so that the aggregated TCO is optimum for a given product manufacture. Based on the simulations and TCO determinations for different configurations and arrangements of the manufacturing machines/equipment, the machines/equipment may be automatically arranged and configured on the industrial floor to achieve an optimum TCO for a given product manufacture. For example, robotic machines/equipment may be automatically controlled to position the robotic machines/equipment at optimal locations on the industrial floor to optimize the overall manufacturing process and sequence to minimize TCO while accommodating customize product manufacture.

The illustrative embodiments provide an improved computing tool and improved computing tool operations/functionality that automatically simulates the manufacturing of a product by industrial floor machines/equipment for a variety of different arrangements and configurations and estimates the TCO for such arrangements and configurations. The improved computing tool and improved computing tool operations/functionality operate to identify the required bill of materials (BOM) and simulate the sequence of operations required to complete the product, and the like, based on the customized needs of a product from the customer, which may include movement of materials to the industrial floor, movement of materials and assemblies of materials between stations of the industrial floor, operations of the various machinery/equipment, and the like, to essentially represent a physical real-world industrial floor manufacture of the customized product as an electronic simulation equivalent. For example, in some illustrative embodiments, a digital twin technology may be used to simulate the industrial floor with various configurations and arrangements of machines and equipment.

Through the electronic simulation of the industrial floor, the mechanisms of the illustrative embodiments simulate the manufacturing workflow of the product to identify the optimum production line that includes the relative position of the machines and equipment involved in working and supporting the process sequence, and the specifications of these machines/equipment, to optimize the TCO of manufacturing the product. In accordance with one or more of the illustrative embodiments, the improved computing tool and improved computing tool operations/functionality evaluates the number of products that have similar customization or provisioning requirements and simulates the process sequence using different arrangements and configurations of machines and equipment to optimize the TCO using cost-benefit analysis and thereby auto-reposition or recommend new positions and orientations of the machines and equipment on the industrial floor based on the simulated results. In accordance with one or more illustrative embodiments, the improved computing tool and improved computing tool operations/functionality evaluates the aggregated non-value-added activities that are required to perform the manufacturing activities and recommends how the working machines/equipment (e.g., metal cutting equipment, etc.) and supporting machines/equipment (e.g., material movement robot, etc.) should be positioned and oriented to optimize the non-value-added activities.

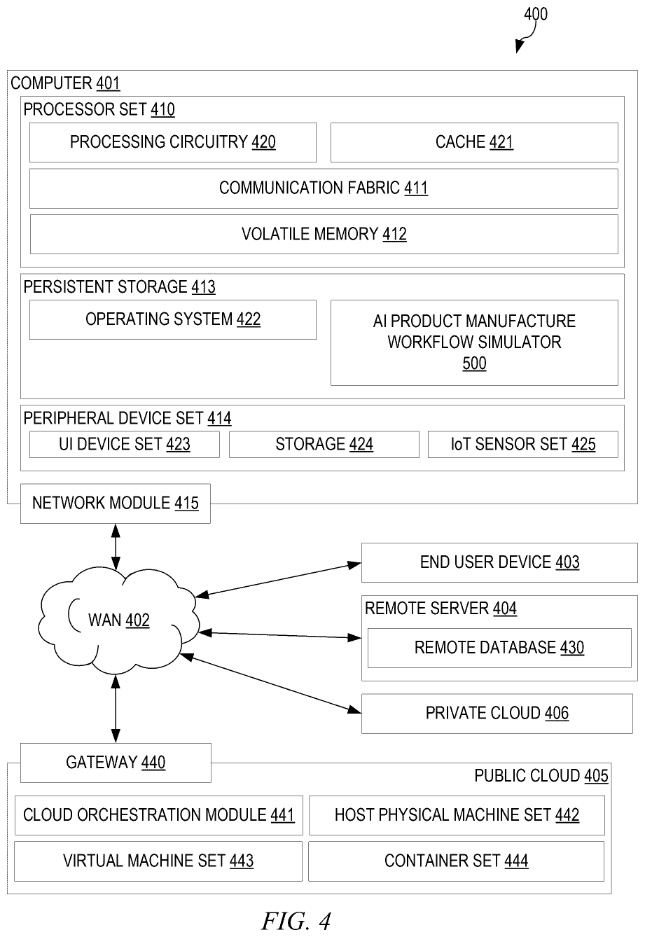

In one or more of the illustrative embodiments, the improved computing tool and improved computing tool operations/functionality evaluate multiple dimensions of the TCO computation (see the example in FIG. 4 above) to perform activities involved in the manufacture of the product. In some illustrative embodiments, the improved computing tool and improved computing tool operations/functionality drive control signals to manufacturing machines/equipment so as to automatically reposition the manufacturing machines/equipment to the determined optimal position, orientation, and internal configurations/settings to implement the simulated optimal industrial floor for the manufacture of the given product(s). In some illustrative embodiments, rather than driving the actual automated arrangement/configuration of the industrial floor, the improved computing tool and improved computing tool operations/functionality may provide a graphical user interface or the like that depicts and describes the recommended new position, orientation, and configuration of the machines/equipment on the industrial floor based on the costs associated with each dimension of TCO for an optimum production line based on the simulations.

In some illustrative embodiments, the improved computing tool and improved computing tool operations/functionality simulates non-value-added activities that are required while performing an activity to manufacture the given product. In these illustrative embodiments, the improved computing tool and improved computing tool operations/functionality searches for machines/equipment available and which have the capabilities required for those identified non-value-added activities, but which can reduce the number of operations required to perform the non-value-added activities, or otherwise optimize the non-value-added activities. Accordingly, the illustrative embodiments of the present invention may operate to recommend machines/equipment that can be replaced or upgraded with different or newer machines/equipment on the industrial floor to optimize TCO.

The illustrative embodiments may provide authorized personnel a total consolidated viewpoint of the industrial floor based on the automated simulations. This total consolidated viewpoint may be provided as a graphical user interface (GUI) that can include a schematic of the industrial floor with the positions and orientations of machines/equipment based on the simulations. Moreover, the total consolidated viewpoint may specify portions of the manufacturing processing determined to be required, non-value-added but essential, and non-value-added and non-essential. The total consolidated viewpoint may specify recommended replacements and upgrades to machines/equipment, estimates of TCO for the configuration of the industrial floor, and the like. In some illustrative embodiments, the total consolidated viewpoint may present different viewpoints for different configurations so that authorized personnel can visualize differences between the various configurations evaluated by the automated AI simulations of the illustrative embodiments.

Thus, the illustrative embodiments provide automated computing tools and computing tool operations/functionality to simulate various arrangements, orientations, and configurations of physical machines/equipment of a physical industrial floor so as to optimize the industrial floor for a particular manufacture workflow for a given product. This requires a complex evaluation of variables of the relative positions/orientations of a plurality of different machines and equipment. The illustrative embodiments optimize this industrial floor with regard to costs and overall TCO for manufacturing the given product, which provides a cost savings to product manufacturers. The illustrative embodiments avoid expensive manual trial and error approaches and allow for rapid and dynamic optimized reconfiguration of industrial floors for customized product manufacture as customer demands change over time. The illustrative embodiments operate to provide automated artificial intelligence (AI) based simulation of a large variety of configurations taking into account a large volume of variables to determine the optimal configuration that reduces overall costs, minimizes non-value-added and non-essential activities, while minimizing the costs of other required or essential activities. Moreover, in some illustrative embodiments, the AI based simulation further evaluates the potential replacement or upgrading of machines and equipment that may reduce overall TCO for the manufacture of the given product.

Consider the following example scenario which further illustrates the applicability of one or more of the illustrative embodiments. Cost accountant(s) are constantly worried about the “total cost of ownership” within various business. Lynnessa, a cost accountant for a large automotive manufacturer, is worried about her manufacturing plant's equipment. Lynnessa needs to optimize the total cost of ownership (TCO) for the manufacturer in order to meet the customer's demands for customized product configurations for specific models of vehicles. Lynnessa utilizes an advanced simulation system, according to one or more of the illustrative embodiments, to model the manufacturing flow, analyze the simulated manufacturing process to identify the most efficient arrangement and relative positions of machines/equipment on the industrial floor, perform cost-benefit analysis to evaluate the financial impact of rearranging machines/equipment, and automatically reposition the machines and equipment to achieve the optimal production line. In addition, the advanced simulation system also identifies the non-value-added activities in the manufacturing process and searches for machines and technologies available in the market to eliminate or streamline these activities. The advanced simulation system may also consider the various cost dimensions such as power consumption, maintenance costs, material movement, labor, and equipment depreciation, to calculate the total cost of ownership associated with different production line configurations. In addition, the advanced simulation system may also be employed by Lynnessa as part of a real-time monitoring and control systems to gather data and use this data for continuous improvement and optimization of the industrial floor. The advanced simulation system thereby provides a total consolidated viewpoint of the industrial floor for the manufacture of a product using advanced simulations and predictions of TCO.

Thus, in accordance with one or more illustrative embodiments, a computing tool and computing tool operations/functionality are provided that implement an advanced simulation to model the manufacturing flow and performs automated repositioning of the machines and equipment on the industrial floor, while evaluating the capabilities of existing machines that need to be upgraded or regularly maintained. In accordance with one or more illustrative embodiments, a computing tool and computing tool operations/functionality are provided that analyze the simulated manufacturing flow to identify the most efficient arrangement and relative positions of working and supporting machines and equipment, perform a cost-benefit analysis to evaluate the financial impact of rearranging machines/equipment and resources, and identifies non-value-added activities in the manufacturing process to search for machines and technologies available in the market that have capabilities to eliminate or streamline these non-value-added activities.

In accordance with some illustrative embodiments, a computing tool and computing tool operations/functionality are provided that recreate non-value-added activities identified in the manufacturing process and evaluate their impact on overall efficiency and cost, where this recreation evaluates various cost dimensions, such as power consumption, maintenance costs, material movement, labor and equipment depreciation to calculate the total cost of ownership associated with different production line configurations. In some illustrative embodiments, a computing tool and computing tool operations/functionality are provided that implement real-time monitoring and control systems to gather data on machine/equipment performance, energy consumption, material flow, and other relevant parameters and use this real-time monitoring and control system data to update the simulations of the industrial floor and automatically reconfigure the positioning, orientation, and configuration of machines/equipment based on dynamically determined optimum arrangements as indicated by the AI mechanisms of the illustrative embodiments.

Before continuing the discussion of the various aspects of the illustrative embodiments and the improved computer operations performed by the illustrative embodiments, it should first be appreciated that throughout this description the term “mechanism” will be used to refer to elements of the present invention that perform various operations, functions, and the like. A “mechanism,” as the term is used herein, may be an implementation of the functions or aspects of the illustrative embodiments in the form of an apparatus, a procedure, or a computer program product. In the case of a procedure, the procedure is implemented by one or more devices, apparatus, computers, data processing systems, or the like. In the case of a computer program product, the logic represented by computer code or instructions embodied in or on the computer program product is executed by one or more hardware devices in order to implement the functionality or perform the operations associated with the specific “mechanism.” Thus, the mechanisms described herein may be implemented as specialized hardware, software executing on hardware to thereby configure the hardware to implement the specialized functionality of the present invention which the hardware would not otherwise be able to perform, software instructions stored on a medium such that the instructions are readily executable by hardware to thereby specifically configure the hardware to perform the recited functionality and specific computer operations described herein, a procedure or method for executing the functions, or a combination of any of the above.

The present description and claims may make use of the terms “a”, “at least one of”, and “one or more of” with regard to particular features and elements of the illustrative embodiments. It should be appreciated that these terms and phrases are intended to state that there is at least one of the particular feature or element present in the particular illustrative embodiment, but that more than one can also be present. That is, these terms/phrases are not intended to limit the description or claims to a single feature/element being present or require that a plurality of such features/elements be present. To the contrary, these terms/phrases only require at least a single feature/element with the possibility of a plurality of such features/elements being within the scope of the description and claims.

Moreover, it should be appreciated that the use of the term “engine,” if used herein with regard to describing embodiments and features of the invention, is not intended to be limiting of any particular technological implementation for accomplishing and/or performing the actions, steps, processes, etc., attributable to and/or performed by the engine, but is limited in that the “engine” is implemented in computer technology and its actions, steps, processes, etc. are not performed as mental processes or performed through manual effort, even if the engine may work in conjunction with manual input or may provide output intended for manual or mental consumption. The engine is implemented as one or more of software executing on hardware, dedicated hardware, and/or firmware, or any combination thereof, that is specifically configured to perform the specified functions. The hardware may include, but is not limited to, use of a processor in combination with appropriate software loaded or stored in a machine readable memory and executed by the processor to thereby specifically configure the processor for a specialized purpose that comprises one or more of the functions of one or more embodiments of the present invention. Further, any name associated with a particular engine is, unless otherwise specified, for purposes of convenience of reference and not intended to be limiting to a specific implementation. Additionally, any functionality attributed to an engine may be equally performed by multiple engines, incorporated into and/or combined with the functionality of another engine of the same or different type, or distributed across one or more engines of various configurations.

In addition, it should be appreciated that the following description uses a plurality of various examples for various elements of the illustrative embodiments to further illustrate example implementations of the illustrative embodiments and to aid in the understanding of the mechanisms of the illustrative embodiments. These examples intended to be non-limiting and are not exhaustive of the various possibilities for implementing the mechanisms of the illustrative embodiments. It will be apparent to those of ordinary skill in the art in view of the present description that there are many other alternative implementations for these various elements that may be utilized in addition to, or in replacement of, the examples provided herein without departing from the spirit and scope of the present invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It should be appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

As described above, the illustrative embodiments provide an artificial intelligence (AI) computing tool and computing tool operations/functionality for performing complex simulations of various arrangements and configurations of machines/equipment of an industrial floor for the manufacture of a given product. The illustrative embodiments simulate the product manufacturing workflow of the industrial floor under various arrangements and configurations and predict the total cost of ownership (TCO) for the various arrangements and configurations. The illustrative embodiments may then select an optimized arrangement/configuration for implementation and/or recommendation which minimizes the TCO as much as possible given any specific constraints. In some cases, the illustrative embodiments may automatically implement the optimized arrangement/configuration as much as possible based on the available autonomous machines/equipment. Moreover, this process may be updated and repeated dynamically as monitoring data is received from the machines/equipment which reflects real-time and real-world operation of the machines/equipment, which thereby updates the simulations and selection of optimized arrangements/configurations.

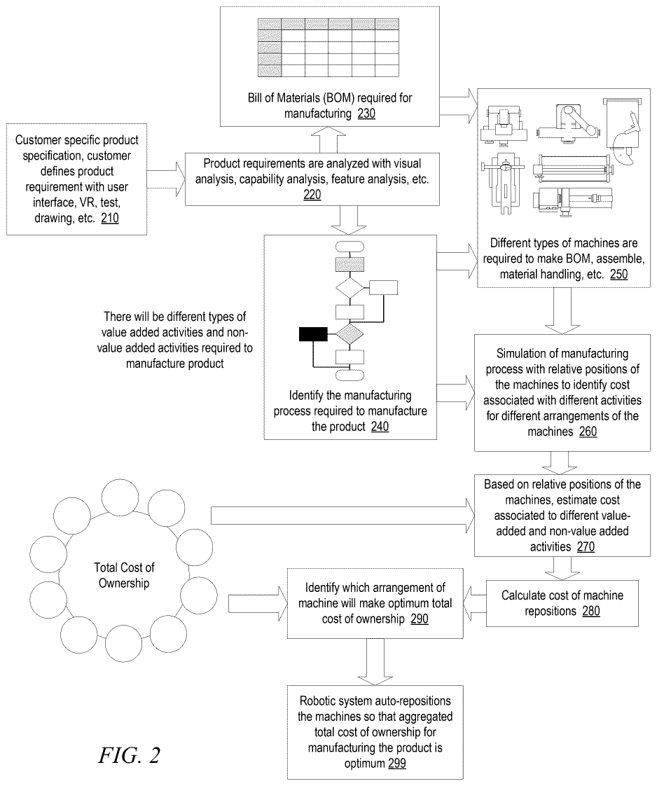

FIG. 2 is an example diagram of a process flow for simulation of a product manufacturing workflow of an industrial floor in accordance with one illustrative embodiment. As shown in FIG. 2, the process comprises a customer providing a specific product specification 210 through which the customer may customize a product for manufacture. The customer may request specific customized configurations of the product via a user interface, textual description, drawings, or any other mechanism by which a data structure or file may be generated and used to convey the information to the improved computing tool of the illustrative embodiments. The specific product specification 210 may be provided via one or more existing tools, such as tools that allow customers to specify product customizations for manufacturing, visual model creation, three dimensional product configurators, and web-based customization platforms. These tools enable users to define product specifications, which are translated into manufacturing requirements.

The data structure representing the product specification is then analyzed by one or more computing tools 220 to extract features and analyze the features to generate a bill of materials (BOM) 230 required for manufacturing and to identify a manufacturing process that would be required to manufacture the customized product 240. One or more existing tools may be used to generate the BOM 230 and a corresponding manufacturing process 240 from product specifications. Such tools leverage computer aided design (CAD) data, product lifecycle management (PLM), and manufacturing execution systems to automate a BOM creation and process planning. The combination of the BOM 230 and the manufacturing process 240 is used to determine the different types of machines and equipment 250 that are required to obtain the elements of the BOM, assemble them, handle the elements of the BOM and the assembled materials, and the like, as part of the manufacturing process.

The different types of machines and equipment 250 along with the manufacturing process 240 are input to the artificial intelligence (AI) product manufacture workflow simulator of the illustrative embodiments 260. The AI product manufacture workflow simulator simulates the various machines and equipment of the industrial floor with regard to specific positions, orientations, and configurations of the machines and equipment and predictions of value-added and non-value-added activities to estimate costs of operation of the various machines and equipment. Each machine and piece of equipment may be represented by different simulation models which are configured for the specific machines/equipment of an industrial floor through configuration parameters. The simulations will simulate the operation of the machine and/or piece of equipment with the combination of simulations being used to simulate the entire industrial floor. In addition, the industrial floor simulation will simulate these machines and equipment from the level of the industrial floor with regard to relative positions, orientations, and configurations of the various machines and equipment.

Thus, the simulations of the machines and equipment will provide information that can be used to determine the costs of operation of the value-added aspects of the manufacturing process. The simulation of the industrial floor will simulate and capture the costs associated with both value-added and non-value-added activities of the industrial floor as a whole (see operation 270). The combination of these will provide a basis for calculating the total cost of operation (TCO) of the manufacture of the particular product for a particular positioning, orientation, and configuration of the machines and equipment of the industrial floor 280. This may be repeated for a plurality of different positionings, orientations, and/or configurations of the machines and equipment so as to provide simulation results for a plurality of possible arrangements of the industrial floor.

From the various TCO predictions for the various arrangements, the illustrative embodiments identify which arrangement of machines/equipment will optimize the TCO given constraints, e.g., performance constraints, industrial floor constrains, and the like 290. In some illustrative embodiments, the selected optimal arrangement may be used to automatically reposition autonomous or robotic machines/equipment and/or instruct human operators to reposition machines/equipment to implement the optimal arrangement that minimizes TCO for manufacturing the product 299. Thus, the mechanisms of the illustrative embodiments optimize the industrial floor for minimized TCO for manufacturing a given product. It should be noted that the simulations utilized may be updated dynamically based on real-time monitoring data gathered from the machines/equipment of the industrial floor. This dynamic updating may lead to a selection of an alternative arrangement of the machines/equipment such that an auto-repositioning and/or instruction to human operators may be again provided so as to implement the dynamically updated selection of the optimal industrial floor arrangement.

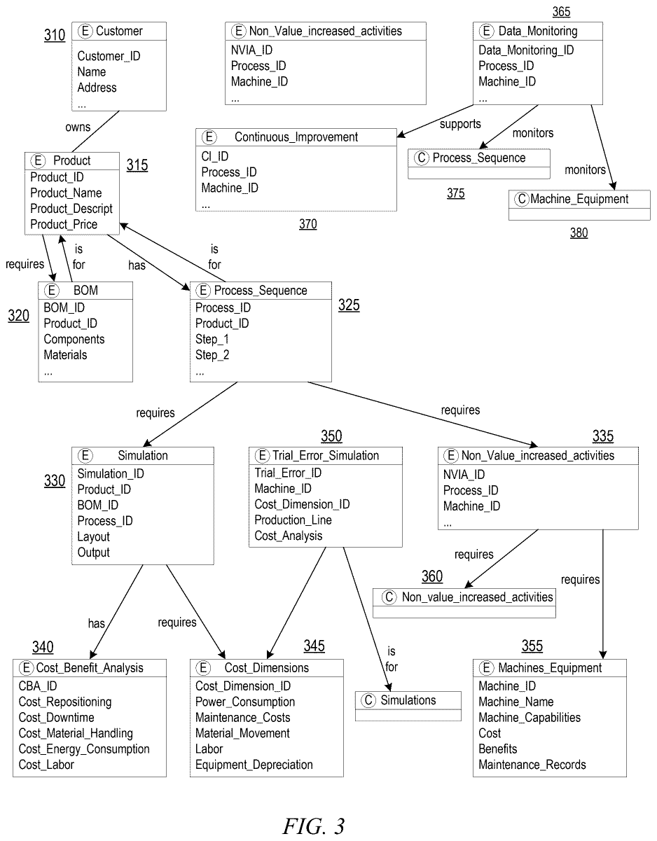

FIG. 3 is an example diagram of an example data entity relationship and data flow diagram for a manufacturing workflow in accordance with one illustrative embodiment. The entity relationship and data flow diagram demonstrates how the various entities are related to one another in a hierarchical manner. Each of the entities have their own corresponding attributes and are connected by edges representing their relationships. For example, a customer 310 has attributes of customer_ID, name, address, phone_number, billing_information, credit_card_information, customization_requirements, and the like. The customization requirements specify how the products for this customer are to be customized for that customer. The customer 310 owns a product 315. The product 315 has attributes of product_ID, product_name, product_description, product_price, and the like. This hierarchy of relationships continues with relationships with a bill of materials (BOM) 320 and manufacturing process_sequence 325. Each of these entities have corresponding attributes as well. The product 315 “requires” the BOM 330 and the BOM 330 “is for” the product 315. Similarly, the product 315 “has” a process_sequence 325, and the process_sequence 325 “is for” the product 315.

Similar relationships continue with the process sequence 325 requiring the simulation 330 and requires non-value-added activities 335. The simulation has a cost benefit analysis 340 and cost dimensions 345. A trial and error simulation 350 also requires the cost dimensions 345 and further “is for” simulations. Moreover, the non-value-added activities 335 require machine equipment 355 and non-value-increased activities 360. Similar relationships also are provided for the data monitoring 365 with entities 370-380.

The hierarchical entity relationship and data flow, such as in the example shown in FIG. 3, enable efficient simulations by organizing data for each manufacturing entity, from product specifications to machine configurations. Each entity's attributes, such as BOM or process sequences, are inputs for AI-driven simulations that evaluate multiple manufacturing setups. This structure facilitates accurate scenario analysis, allowing the system to dynamically identify optimal Total Cost of Ownership arrangements. By using real-time sensor feedback, the illustrative embodiments refine these simulations, ensuring the selected configurations maximize efficiency, minimize costs, and address inefficiencies like non-value-added activities. The result is a continuous feedback loop optimizing industrial floor performance.

As is clear from the above description, the improved computing tool and improved computing tool operations/functionality of the illustrative embodiments may be provided by way of a specifically configured computing system, configured with hardware and/or software that is itself specifically configured to implement the particular mechanisms and functionality described herein, a method implemented by the specifically configured computing system, and/or a computer program product comprising software logic that is loaded into a computing system to specifically configure the computing system to implement the mechanisms and functionality described herein. Whether recited as a system, method, of computer program product, it should be appreciated that the illustrative embodiments described herein are specifically directed to an improved computing tool and the methodology implemented by this improved computing tool. In particular, the improved computing tool of the illustrative embodiments specifically provides an artificial intelligence (AI) product manufacture workflow simulation mechanism that determines optimal positioning, orientation, and configuration of machines/equipment of an industrial floor for the manufacture of a given product, with this simulation being performed dynamically based on real-time monitoring of machines/equipment and further based on dynamic updating of demands for customized products. The improved computing tool implements mechanism and functionality, such as the AI product manufacture workflow simulator, which cannot be practically performed by human beings either outside of, or with the assistance of, a technical environment, such as a mental process or the like. The improved computing tool provides a practical application of the methodology at least in that the improved computing tool is able to optimize the arrangement of an industrial floor dynamically in order to reduce overall total cost of ownership (TCO) for the manufacture of products.

FIG. 4 is an example diagram of a distributed data processing system environment in which aspects of the illustrative embodiments may be implemented and at least some of the computer code involved in performing the inventive methods may be executed. That is, computing environment 400 contains an example of an environment for the execution of at least some of the computer code involved in performing the inventive methods, such as AI product manufacture workflow simulator 500. In addition to AI product manufacture workflow simulator 500, computing environment 400 includes, for example, computer 401, wide area network (WAN) 402, end user device (EUD) 403, remote server 404, public cloud 405, and private cloud 406. In this embodiment, computer 401 includes processor set 410 (including processing circuitry 420 and cache 421), communication fabric 411, volatile memory 412, persistent storage 413 (including operating system 422 and AI product manufacture workflow simulator 500, as identified above), peripheral device set 414 (including user interface (UI), device set 423, storage 424, and Internet of Things (IoT) sensor set 425), and network module 415. Remote server 404 includes remote database 430. Public cloud 405 includes gateway 440, cloud orchestration module 441, host physical machine set 442, virtual machine set 443, and container set 444.

Computer 401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

Processor set 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in AI product manufacture workflow simulator 500 in persistent storage 413.

Communication fabric 411 is the signal conduction paths that allow the various components of computer 401 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 412 is any type of volatile memory now known or to be developed in the future. Examples include dynamic type random access memory (RAM) or static type RAM. Typically, the volatile memory is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

Persistent storage 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface type operating systems that employ a kernel. The code included in AI product manufacture workflow simulator 500 typically includes at least some of the computer code involved in performing the inventive methods.

Peripheral device set 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing very large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

Network module 415 is the collection of computer software, hardware, and firmware that allows computer 401 to communicate with other computers through WAN 402. Network module 415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 415 are performed on the same physical hardware device. In other embodiments (for example, embodiments that utilize software-defined networking (SDN)), the control functions and the forwarding functions of network module 415 are performed on physically separate devices, such that the control functions manage several different network hardware devices. Computer readable program instructions for performing the inventive methods can typically be downloaded to computer 401 from an external computer or external storage device through a network adapter card or network interface included in network module 415.

WAN 402 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 403 is any computer system that is used and controlled by an end user (for example, a customer of an enterprise that operates computer 401), and may take any of the forms discussed above in connection with computer 401. EUD 403 typically receives helpful and useful data from the operations of computer 401. For example, in a hypothetical case where computer 401 is designed to provide a recommendation to an end user, this recommendation would typically be communicated from network module 415 of computer 401 through WAN 402 to EUD 403. In this way, EUD 403 can display, or otherwise present, the recommendation to an end user. In some embodiments, EUD 403 may be a client device, such as thin client, heavy client, mainframe computer, desktop computer and so on.

Remote server 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

Public cloud 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 405 is performed by the computer hardware and/or software of cloud orchestration module 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration module 441 manages the transfer and storage of images, deploys new instantiations of VCEs and manages active instantiations of VCE deployments. Gateway 440 is the collection of computer software, hardware, and firmware that allows public cloud 405 to communicate through WAN 402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

As shown in FIG. 4, one or more of the computing devices, e.g., computer 401 or remote server 404, may be specifically configured to implement a AI product manufacture workflow simulator 500. The configuring of the computing device may comprise the providing of application specific hardware, firmware, or the like to facilitate the performance of the operations and generation of the outputs described herein with regard to the illustrative embodiments. The configuring of the computing device may also, or alternatively, comprise the providing of software applications stored in one or more storage devices and loaded into memory of a computing device, such as computer 401 or remote server 404, for causing one or more hardware processors of the computing device to execute the software applications that configure the processors to perform the operations and generate the outputs described herein with regard to the illustrative embodiments. Moreover, any combination of application specific hardware, firmware, software applications executed on hardware, or the like, may be used without departing from the spirit and scope of the illustrative embodiments.

It should be appreciated that once the computing device is configured in one of these ways, the computing device becomes a specialized computing device specifically configured to implement the mechanisms of the illustrative embodiments and is not a general purpose computing device. Moreover, as described hereafter, the implementation of the mechanisms of the illustrative embodiments improves the functionality of the computing device and provides a useful and concrete result that facilitates automated AI simulation of the machines/equipment of an industrial floor under various possible positions, orientations, and configurations, as well as alternative machines/equipment, for the production of a given product so as to optimize the industrial floor to minimize TCO of the manufacture of the product. The illustrative embodiments further provide mechanisms for the automated implementation of the optimized arrangement of the industrial floor through the sending of control signals and the like to robotic or otherwise autonomous machines/equipment so as to position, orient, and/or configure the machines/equipment dynamically for optimized manufacture of the given product.

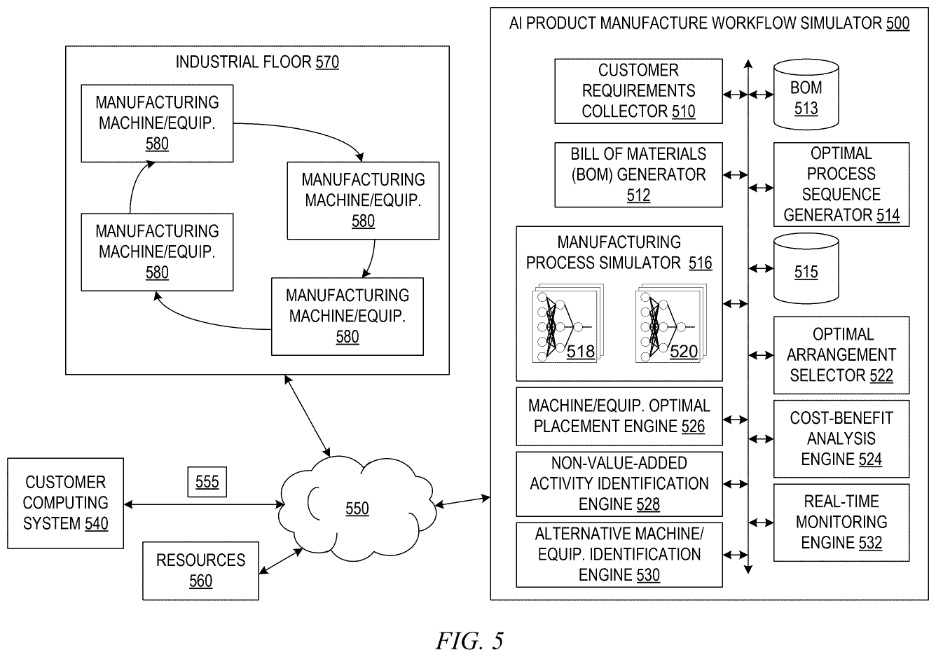

FIG. 5 is an example block diagram of the primary operational components of an artificial intelligence (AI) product manufacture workflow simulator in accordance with one illustrative embodiment. The operational components shown in FIG. 5 may be implemented as dedicated computer hardware components, computer software executing on computer hardware which is then configured to perform the specific computer operations attributed to that component, or any combination of dedicated computer hardware and computer software configured computer hardware. It should be appreciated that these operational components perform the attributed operations automatically, without human intervention, even though inputs may be provided by human beings, e.g., search queries, and the resulting output may aid human beings. The invention is specifically directed to the automatically operating computer components directed to improving the physical positioning, orientation, and configuration of machines and equipment of an industrial floor so as to reduce overall TCO based on AI simulation of various potential arrangements taking into consideration a large number of variables and relative configurations, alternative machine/equipment possibilities, and the like, which cannot be practically performed by human beings as a mental process and is not directed to organizing any human activity. Moreover, such operations may be performed dynamically as monitoring data is received from industrial floor machines/equipment and customized product specifications are received. Furthermore, the mechanisms of the illustrative embodiments may drive control signals to machines/equipment to physically alter their positions, orientations, and configurations automatically to achieve the optimized arrangements, which again cannot be practically performed mentally.

As shown in FIG. 5, the AI product manufacture workflow simulator 500 comprises a customer requirements collector 510, a bill of materials (BOM) generator 512, an optimal process sequence generator 514, and manufacturing process simulator 516 having one or more machine/equipment simulation models 518 and one or more industry floor models 520. The AI product manufacture workflow simulator 500 further comprises an optimal arrangement selector 522, a cost-benefit analysis engine 524, a machine/equipment optimal placement engine 526, a non-value-added activity identification engine 528, an alternative machine/equipment identification engine 530, and a real-time monitoring engine 532.

The customer requirements collector 510 comprises computer logic that collects from a customer, via a customer computing device 540 and one or more data networks 550, a customer requirements and customization needs data structure 555 for a product. In some illustrative embodiments, the data structure 555 may be generated using any known or later developed product specification application and interface which generates a structured data structure comprising information including specifications, features, and any specific design requests that the customer has for a specific product that is to be manufactured. In some illustrative embodiments, the customer computing device 540 may submit a non-structured natural language document describing the requested specification, features, and design requests for the specific product which may then be processed by the customer requirements collector 510 using natural language processing (NLP) configured specifically for extracting features indicative of product specifications, features and design requests. For example, the NLP mechanisms may comprise dictionaries, synonyms, ontologies, named entity recognition logic, and the like, that are specifically directed to product specifications and specifically customized for such extraction of features from natural language content in a customer requirements and customization needs data structure 555.

Based on the processing of the data structure 555 through structured and/or non-structured natural language processing to extract features from the data structure 555, the BOM generator 512 generates a comprehensive BOM that includes all the necessary components, materials, and sub-assemblies required to manufacture the product based on the customer's requirements as specified in the data structure 555. That is, the extracted features are input to the BOM generator 512 which then processes these extracted features to identify the particular components, materials, and sub-assemblies required. The BOM generator 512 may comprise one or more AI computer models that are specifically trained, through machine learning training processes, to take a set of input features, analyze the set of input features to determine patterns, and correlate these patterns with particular outputs which may be classifications, predictions, or the like. In this particular case, the AI computer models may take features representing customer specifications for a product and from those features determine a listing of BOM elements for producing the product.

It should be appreciated that the present invention makes use of a number of different AI computer models to perform operations for determining the optimal industrial floor arrangement for a given product manufacture, and that these AI computer models are specifically trained through machine learning training processes to perform their attributed specific functions, making them each application specific AI computer models. This machine learning training process for each AI computer model is based on a corresponding training dataset comprising examples of input features that represent the types of input features the AI computer model is expected to see during runtime operation. Moreover, the training dataset comprises ground truth labels which specify the correct output that the AI computer model should generate based on these input features if the AI computer model is operating properly. During the machine learning training process, the AI computer model receives an training data example as input, generates an output based on its current configuration, and that output is compared to the ground truth label to determine an error or loss. A machine learning training function is then applied to this error or loss to attempt to minimize this error or loss. Based on the application of the machine learning training function, modifications of the AI computer model's internal configuration parameters are made to implement this minimization of the error or loss. This process is repeated for each example in the training dataset and may be repeated over a plurality of iterations or epochs until a convergence criteria is met, e.g., a predetermined number of iterations have occurred or the error/loss is reduced down to a predetermined threshold or less. Once trained, a testing dataset, similar to the training dataset, may be applied to verify the performance of the AI computer model prior to deployment of the AI computer model for runtime operation against previously unseen combinations of input features.

With the AI computer models of the present invention, the training is tailored to the specific types of input features that the particular AI computer model is expected to process during runtime operation. The training dataset comprises examples of those input features and subject matter expert annotated ground truth labels. Thus, different training datasets may be used with different AI computer models and the AI computer models may be trained separately to perform their corresponding functions based on their specific training datasets.

It should be appreciated that in some illustrative embodiments, the AI computer models may be previously trained language models (LMs) or large language models (LLMs) which may use prompt inputs that specify to the LM/LLM what their function is, what tools they can use, the context upon which the LM/LLM is to operate, and what types of outputs that the LM/LLM is to generate. That is, rather than having to train specific AI computer models as in the above description, in some illustrative embodiments, the mechanisms of the present invention may leverage the power of previously trained LM/LLMs, which are trained on a vast amount of input data but are more generally trained. The specific prompts input to the LM/LLM narrow the focus of the LM/LLM to the particular inputs and function that is desired to be performed, thereby fine-tuning the LM/LLM to the particular function. These prompts may be generated based on predefined templates which are then populated with the specific input feature values and context information to thereby generate the specific prompt.

With regard to the BOM generator, the BOM generator 512 may not only receive as input the features extracted from the customer's specification in the data structure 555, but may also receive inputs from other resources 560, such as product specific ontologies, parts listings, electronic trade publications, assembly manuals, materials providers, assembly providers, or any other source of information about the specific parts, materials, and sub-assemblies that may be used to produce the product. Thus, these resources 560 may provide a baseline set of information about what is available to produce the product while the extracted features from the data structure 555 may provide the information regarding the specific customer requirements and customizations of that product. By combining and processing the information from these sources, the BOM generator 512 is able to determine which components, parts, and sub-assemblies are required for producing the product having the customer requirements and customizations.

The BOM 513 generated by the BOM generator 512 is provided to the optimal process generator 514 which generates an optimal process data structure 515 detailing the specific steps of a process for the manufacture of the product using the BOM 513. The optimal process generator 514 comprises logic that determines the particular order in which components, parts, and sub-assemblies may be handled and combined in order to generate the particular product. The logic of the optimal process generator 514 may utilize resources specifying the types, quantities, and capabilities of the machines/equipment available for producing the product, as well as the predefined set of assembly or manufacturing steps required to perform the manufacture of the product. These steps may be correlated to the BOM 513 and may be modified as needed to accomplish the particular customer requirements and customizations for the product.

For example, a BOM 513 for an electric car may include a chassis, electric motors, batteries, wheels, interior components, and electronic control units. The processing sequence for the electric car involves chassis fabrication, motor installation, battery integration, interior assembly, and final testing. The specification of these process steps, as well as their sequence, may be provided in a predefined document of manufacturing steps for the particular product, e.g., the electric car in the above example, and these steps may be modified as needed to implement the particular customer's requirements or customizations, e.g., a step of solar panel installation may be added if the customer requests a solar power option for the particular product.

Having generated the BOM 513 and the optimal process sequence 515 based on the BOM and the predefined manufacturing process, potentially modified to implement the customer's requirements and customizations, the manufacturing process simulator 516 operates on these as inputs to simulate the manufacture of the product. The manufacturing process simulator 516 comprises one or more machine/equipment simulation models 518 and one or more industrial floor models 520. The machine/equipment simulation models 518 may implement a digital twin technology, for example. Digital twin technology refers to a virtual model designed to accurately reflect a physical object or machine. In digital twin technology, a real-time digital counterpart of the physical object or machine may be generated based on a model generated from monitoring the physical object or machine with various sensors related to the important operational aspects of the object or machine. This information is then used to generate a virtual model of that physical object or machine. In the present case, the digital twin models 518 model the operation of machines and equipment 580 of an industrial floor 570 which are used for manufacturing the product. Of course, digital twin technology is not required for the implementation of the present invention, and any other types of simulation models may be used to model the machines and/or equipment used in the manufacture of the given product, without departing from the spirit and scope of the present invention.

While the one or more machine/equipment simulation models 518 model their respective individual machines/equipment 580 on the industrial floor 570, the one or more industrial floor models 520 model the overall industrial floor 570 comprising the combination of machines and equipment 580. The one or more industrial floor models 520 model the interactions between machines/equipment 580, the transport of materials, parts, and sub-assemblies between machines/equipment, personnel for operating the machines/equipment, and various other conditions, operations, and the like of the industrial floor 570 at the industrial floor level. The one or more industrial floor models 520 utilize advanced simulation software to model the manufacturing flow based on the identified BOM 513, optimal process sequence data structure 515, and machine/equipment simulation models 518. This enables virtual testing and optimization of the manufacturing process. For example, computer-aided manufacturing (CAM) software may be utilized to simulate the assembly line, virtualizing the movement of components, tool paths, and timing of operations.

To model the industrial floor, each piece of machinery/equipment may be represented as an independent simulation model, capturing its specific operations, constraints, and interactions. These individual models may then be integrated into a larger AI-based system that simulates the entire industrial floor, including spatial layout, equipment interdependencies, and workflow dynamics. This hierarchical modeling framework enables simulations of various equipment configurations, facilitating the identification of optimal arrangements. Real-time sensor data further refines simulations, ensuring alignment with actual performance metrics. This approach supports dynamic reconfigurations, cost-benefit analyses, and adaptive optimization based on manufacturing requirements.

The one or more industrial floor models 520, which again may be AI computer models trained to simulate an industrial floor based on outputs from the individual machine/equipment simulation models 518, may be used to simulate various arrangements of the machines/equipment on the industrial floor 570, where the particular arrangements simulated may be dependent upon industrial floor constraints, e.g., the industrial floor may have physical constraints that reduce the number of possible positions/orientations for pieces of machinery/equipment. These arrangements involve various positioning, orientation, and configurations of the machines/equipment as well as any pathways between such machines/equipment. The arrangements allow for exploration of various ways to configure the industrial floor with regard to relative positioning, orientation, and configuration of machines/equipment with one another. Each simulation of each arrangement will generate particular outputs as to performance metrics for the individual machines/equipment and the industrial floor as a whole.

For example, the simulations may evaluate various industrial floor layouts using key performance metrics, such as Total Cost of Ownership (TCO), manufacturing time, and material costs. Each simulation outputs these metrics based on real-time production constraints, resource utilization, and efficiency. An optimal arrangement balances these factors by minimizing a weighted cost function. For example, a non-limiting weighted cost function that may be utilized may be of the type:

$$Optimal Score = w 1 \times TCO + w 2 \times Manufacturing Time + w 3 \times Material Costs ,$$

where w1, w2, and w3 are user-defined weights reflecting organization priorities. Analysis involves iterating layouts to minimize this score, ensuring balanced trade-offs and achieving the most cost-effective and efficient configuration. It should be appreciated that this is only one example of a weighted cost function that may be used and any modifications of this cost function may be made, such as including other weights and metrics in addition to, or in replacement of, those shown above without departing from the spirit and scope of the present invention.

Thus, the simulations may generate performance metrics along the lines of the various cost dimensions of the TCO as shown in FIG. 1 discussed above, e.g., power consumption, maintenance costs, material movement, labor, equipment depreciation, and the like, to calculate the total cost of ownership (TCO) associated with different arrangements and production line configurations. For example, the illustrative embodiments may calculate the energy consumption of machines, analyze maintenance records for historical costs, and factor in labor expenses to determine the overall TCO for a given arrangement.

The simulations of the various arrangements of the industrial floor 570 by the industrial floor models 520 may employ an automated trial-and-error approach to iteratively reposition machines/equipment on the industrial floor, simulating different production line layouts and evaluating the associated costs for each dimension of the TCO. In this way, the industrial floor models 520 may automatically experiment with different arrangements of assembly stations, material handling robots, and inspection stations, for example, to find the arrangement that minimizes costs and maximizes efficiency. The resulting performance metrics for each arrangement, e.g., the cost dimensions of the TCO, generated by this automated trial-and-error approach may then be evaluated to identify the production line layout that achieves the optimal TCO for manufacturing the product. For example, the evaluation may analyze the simulated costs associated with different layouts, considering factors such as reduced material handling, optimized workflow, and improved resource utilization.

Thus, the performance metrics for the various simulations of the industrial floor are input to the optimal arrangement selector 522 which analyzes the simulated manufacturing flow for the various arrangements based on the performance metrics, such as mentioned above. The analysis may take many different forms but involves a specific set of computer logic for evaluating the performance metrics against desired performance criteria for a given customer/manufacturer. For example, the performance criteria may comprise a desire to minimize material handling, which may be translated to minimizing transportation of materials between stations of the industrial floor 570. In such a case, the optimal arrangement selector 522 may select an arrangement with relative positions of working and supporting machines/equipment 580 on the industrial floor 570 which optimize the performance metrics with a specific goal of minimizing material handling related performance metrics. A combination of performance criteria may be specified and may be optimized through a balancing of the various performance metrics to maximize or minimize the particular performance criteria and obtain an optimal result and corresponding arrangement of the machines/equipment 580 of the industrial floor 570.

In this way, the optimal arrangement selector 522 determines the most efficient arrangement and relative positions of working and supporting machines/equipment 580 on the industrial floor 570 for a given set of performance criteria based on the simulations of the industrial floor 570 performed by the one or more industrial floor models 520 of the manufacturing process simulator 516. For example, the optimal arrangement selector 522 may determine the layout for placing assembly stations, welding robots, paint booths, conveyor systems, and quality control checkpoints of the industrial floor 570 so as to minimize material handling and optimize production efficiency.

Having identified an optimal arrangement of the machines/equipment 580 of the industrial floor 570 based on the simulations and performance criteria, the cost-benefit analysis engine 524 may operate to perform a cost-benefit analysis to evaluate the financial impact of rearranging machines, equipment, and resources to align with the selected optimal arrangement of the industrial floor 570. For example, the cost-benefit analysis engine 524 may calculate the costs associated with repositioning machines, potential downtime during the transition, and the expected savings in material handling, energy consumption, and labor costs.

The cost-benefit analysis evaluates both operational costs and performance improvements. Costs include direct expenses like rearranging equipment, while benefits are quantified by assessing improvements in efficiency, production speed, and reduced waste. The benefits can be modeled via simulations using machine learning algorithms to optimize the arrangement of manufacturing equipment. If the cost exceeds a threshold, the mechanisms of the illustrative embodiments may flag the simulation for review rather than implementing the optimal arrangement automatically. This ensures informed decision-making, aligning equipment placement with both cost-efficiency and productivity goals. Based on the cost-benefit analysis, an optimal arrangement of manufacturing equipment is selected based on simulations and real-time data. The cost-benefit analysis informs decisions like reducing equipment ownership costs or addressing non-value-added activities and optimizing equipment arrangement and manufacturing processes. This suggests that cost considerations are part of the optimization but do not solely dictate the process, reflecting a balance between efficiency and cost.

The machine/equipment optimal placement engine 526 operates to automatically reposition the machines and equipment 580 on the industrial floor 570 to achieve the identified optimal arrangement of the industrial floor 570 and thus, the optimal arrangement of the production line for producing the product. For example, this repositioning may comprise the machine/equipment optimal placement engine 526 sending control signals to robotic systems, autonomous systems, and the like, to reposition these systems in accordance with the optimal arrangement of the industrial floor 570. This may utilize robotic systems, conveyor systems with adjustable positions, and programmable logic controllers (PLCs) to move and rearrange machines/equipment according to the determined layout, sensors to verify the proper positioning, orientation, and configuration, and various digital communications back and forth between the machines/equipment 580 and the machine/equipment optimal placement engine 526 to ensure the proper arrangement in accordance with the selected optimal arrangement is achieved.

It should be appreciated that while robotic or autonomous machines/equipment may be utilized, the illustrative embodiments do not require such. To the contrary, in some illustrative embodiments, this repositioning may alternatively, or in addition, involve sending instructions, messages, and the like, to personnel computing devices to instruct them on how to rearrange the machines/equipment 580 of the industrial floor to realize the selected optimal arrangement. As noted above, sensors may be utilized, e.g., positioning sensors on the machines/equipment 580 themselves and/or sensors, cameras, or the like, located in the environment of the industrial floor 570, to verify proper arrangement of the machines/equipment 580 whether performed automatically or with manual efforts. Thus, a fully automated rearrangement, partially automated rearrangement, or manual rearrangement of the machines/equipment 580 of the industrial floor is made possible by the mechanisms of the illustrative embodiments.

In some illustrative embodiments, as part of the selection of the optimal arrangement by the optimal arrangement selector 522, the non-value-added activity identification engine 528 may identify non-value-added activities in the manufacturing process, which do not directly contribute to the final product or customer satisfaction but add to the overall cost and time of manufacturing the product. The illustrative embodiments evaluate whether a task directly contributes to the final product or customer satisfaction. For example, the non-value-added activity identification engine 528 may identify tasks such as excessive material handling, waiting times, redundant inspections, or inefficient tool changeovers during production. The non-value-added activity identification engine 528 analyzes production flows, detecting inefficiencies, and correlates them with potential solutions such as upgraded machinery or optimized processes. This evaluation is based on performance metrics like time, cost, and resource utilization. By assessing these factors, the system determines opportunities for eliminating or streamlining non-value-added activities to improve overall efficiency. For these non-value-added activities identified by the non-value-added activity identification engine 528, the alternative machine/equipment identification engine 530 may operate to search for machines, equipment, and technologies available in the market that have capabilities to eliminate or streamline the identified non-value-added activities, improving overall production efficiency.

Such searching may be performed with regard to the various resources 560 that specify the available machines/equipment and their capabilities with regard to the particular performance metrics corresponding to the inefficiencies identified as part of the non-value-added activities. For example, the alternative machine/equipment identification engine 530 may explore advanced robotic arms with vision systems for automated material handling, robotic welding systems for faster and more accurate welding, or automated inspection systems for quality control. Moreover, such searching for alternative machines/equipment may also consider upgrading existing machines/equipment 580 of the industrial floor 570 to newer models having improved capabilities. Such upgrade analysis may involve evaluate the capabilities of existing machines/equipment and determining which machines/equipment may be upgraded or undergo maintenance to optimize their capabilities and thereby reduce the total cost of ownership while ensuring reliable performance.

For example, the alternative machine/equipment identification engine 530 may operate to assess the condition and performance of CNC milling machines, robotic welders, and other critical equipment, and plan for maintenance schedules and upgrades to enhance productivity and minimize downtime. The analysis and evaluation of machine or equipment upgrades and maintenance are based on performance metrics such as operational efficiency, downtime, and cost-benefit analysis. The illustrative embodiments may use real-time data from sensors and simulations to identify non-value-added activities like excessive material handling or delays. Equipment condition, maintenance history, and performance discrepancies are evaluated to determine if an upgrade or maintenance is necessary. If the analysis suggests significant cost savings or efficiency gains, an upgrade or maintenance recommendation is made. Sensors and AI models continually update the system based on real-time feedback.

Based on the analysis and assessment of the non-value-added activities and alternative machines/equipment, recommendations may be generated for output to authorized personnel for improving the currently determined optimal arrangement of the industrial floor 570. Thus, the authorized personnel are informed as to what modifications can be made to the machines/equipment 580 of the industrial floor 570 to improve the overall production line and manufacture of the product, supporting decision making for replacement, upgrade, and maintenance of the machines/equipment 580.

In some illustrative embodiments, the AI product manufacture workflow simulator 500 may further operate based on real-time monitoring data obtained by real-time monitoring engine 532 from sensors and computing systems associated with the various machines/equipment 580 of the industrial floor 570. The real-time monitoring engine 532 may receive data on machine performance, energy consumption, material flow, and other relevant performance parameters from these sensors and computing systems and use this data for continuous improvement and optimization of the AI product manufacture workflow simulator 500. For example, sensors may be installed on the machines/equipment 580 to collect data on their operational parameters, and have these sensors integrated with a supervisory control and data acquisition (SCADA) system for centralized monitoring and control. The collected data may be regularly reviewed and analyzed to identify opportunities for further optimization and cost reduction. For example, real-time monitoring engine 532 may operate to identify bottlenecks in the production line which were not recognized by the automated workflow simulations, may identify opportunities for streamlining the production line processes, optimize machine utilization, and the like, so as to increase productivity and reduce costs.

In some illustrative embodiments, the optimization process may start by collecting data on existing equipment and manufacturing workflows. The illustrative embodiments use machine learning models to simulate different floor arrangements, assessing factors like machine efficiency, operational costs, and time spent on non-value-added activities. The illustrative embodiments then select the best layout, factoring in real-time data, and identifies non-value-added activities. This data is used to recommend equipment upgrades, replacements, or maintenance, enhancing performance. A cost-benefit analysis is performed to ensure the new configuration reduces ownership costs and maximizes productivity. Automated systems then implement the optimal arrangement.

The identification of opportunities for improvement may be fed back into the AI product manufacture workflow simulator 500 to update the data for the various machines/equipment and industrial floor that are utilized by the simulation models 518 and 520 to thereby update the performance metrics and again perform simulations of various arrangements of the industrial floor 570 to determine an optimal arrangement based on the updated real-time data. In this way, the real-time monitoring engine 532 may operate in conjunction with the other elements of the AI product manufacture workflow simulator 500 to implement continuous improvement initiatives to enhance the overall manufacturing process and the simulations performed by the AI product manufacture workflow simulator 500. By continuously monitoring and adapting the production line configuration and machine/equipment 580 arrangement to accommodate changing customer demands and customization requirements, an improved manufacturing of products is achieved that reduces TCO, which ultimately leads to reduced costs for customers. Such adaptations may include modify the production line layout and machine/equipment positions to accommodate new product variants or changes in production volume based on customer orders.

In some illustrative embodiments, this real-time monitoring by the real-time monitoring engine 532 may further include the establishment of a feedback loop to capture feedback from operators, maintenance personnel, and other stakeholders. This feedback information from the human personnel may be used to refine the simulation models, optimize machine/equipment positions, and improve the overall AI product manufacture workflow simulator 500 performance. For example, the real-time monitoring engine 532 may regularly solicit feedback from operators regarding machine ergonomics, process efficiency, and any identified issues to drive continuous improvement and refine the AI product manufacture workflow simulator 500 effectiveness.

Thus, the illustrative embodiments provide an improved computing tool and improved computing tool operations/functionality for dynamically and automatically optimizing the arrangement of machines/equipment of an industrial floor. The illustrative embodiments implement specific AI computing models to simulate the operation of the machines/equipment in various arrangements and evaluate the various arrangements with regard to a plurality of dimensions of a total cost of ownership as well as performance criteria. An optimal arrangement of the machines/equipment of the industrial floor may be selected based on such evaluations and used to automatically, semi-automatically, or manually reposition machines/equipment to implement the selected optimal arrangement. The optimal arrangement may be further evaluated for inefficiencies with regard to non-value-added activities. The illustrative embodiments may then search for alternative machines/equipment and the like to address these inefficiencies and provide recommendations. The illustrative embodiments may also perform real-time monitoring to collect real-time data and personnel feedback to feed back into the simulations to improve the selection of optimized arrangements of machines/equipment of an industrial floor and drive dynamic modification of the arrangements as deemed appropriate.

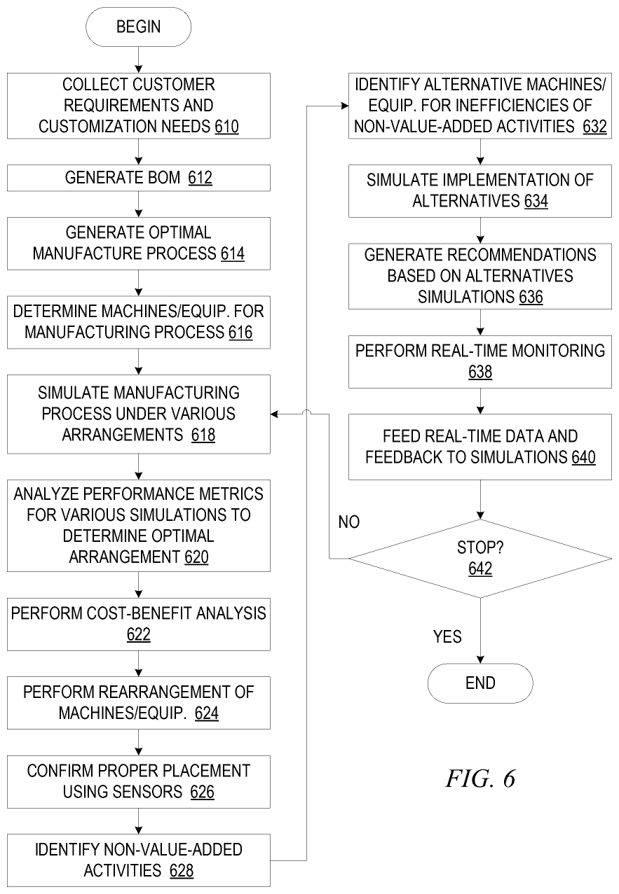

FIG. 6 is a diagram illustrating a flowchart of an example operation of an AI product manufacture workflow simulator in accordance with one illustrative embodiment. It should be appreciated that the operations outlined in FIG. 6 are specifically performed automatically by an improved computer tool of the illustrative embodiments and are not intended to be, and cannot practically be, performed by human beings either as mental processes or by organizing human activity. To the contrary, while human beings may, in some cases, initiate the performance of the operations set forth in FIG. 6, and may, in some cases, make use of the results generated as a consequence of the operations set forth in FIG. 6, the operations in FIG. 6 themselves are specifically performed by the improved computing tool in an automated manner.

As shown in FIG. 6, the operation starts by collecting customer requirements and customization needs for a product that is to be manufactured (step 610). This information may be obtained by processing a structured and/or unstructured data structure comprising the specification for the desired product, from which features are extracted that may be used to identify required materials, parts, sub-assemblies and the like, as well as manufacturing processes. A comprehensive BOM is generated based on the extracted features (step 612) and an optimal sequence of manufacturing processes required to manufacture the product is generated (step 614). The particular machines/equipment required to perform the various steps of the optimal manufacturing process sequence are then identified (step 616).

Simulation models are implemented, both for the individual machines/equipment and for the industrial floor as a whole, to simulate the manufacturing of the product based on the identified BOM and optimal manufacturing process sequence to thereby simulate the manufacturing process under various arrangements (step 618). The performance metrics generated for each simulation of each arrangement are then analyzed to determine an optimal arrangement given placement constraints of the industrial floor and performance criteria (step 620). The optimal arrangement is further analyzed using a cost-benefit analysis to determine the costs and benefits of rearranging the machines/equipment and resources to align with the optimal arrangement identified through the simulations (step 622). Assuming that the cost-benefit analysis does not indicate an unacceptable cost-benefit scenario, a rearrangement of the machines/equipment of the industrial floor is performed in accordance with the selected optimal arrangement (step 624). This rearrangement may involve sending control signals to autonomous or robotic machines/equipment, sending instructions to personnel to perform repositioning, orientation and configuration of the machines/equipment, or a combination of such. Moreover, sensors on the machines/equipment and/or in the environment of the industrial floor may be used to confirm proper rearrangement (step 626).

Based on the selected optimal arrangement, non-value-added activities involved in the manufacturing of the product with this arrangement are identified (step 628). Alternative machines/equipment to address the inefficiencies of the non-value-added activities may then be identified (step 630). In addition, upgrades, maintenance opportunities, and the like, may be identified for addressing these inefficiencies (step 632). The simulation tools above may be used to simulate the implementation of these alternative machines/equipment, upgrades, and maintenance opportunities with regard to the non-value-added activities so as to identify ones that improve the elements of the TCO and performance metrics of the selected optimal arrangement (step 634). The alternatives, upgrades, and maintenance opportunities determined to improve the performance and TCO may be used to generate recommendation outputs to authorized personnel to consider implementing these possibilities (step 636).

Real-time monitoring of the machines/equipment in the rearranged industrial floor is performed to collect real-time data and personnel feedback information (step 638). The real-time monitoring data and feedback information may then be fed back into the simulations to update the simulations (step 640) and choose an updated optimal arrangement of the industrial floor by repeating the above process based on the real-time data and feedback information updates to the simulations. This process may be repeated periodically or continuously until a stopping condition is detected (step 642) at which point the operation is terminated.

The description of the present invention has been presented for purposes of illustration and description, and is not intended to be exhaustive or limited to the invention in the form disclosed. Many modifications and variations will be apparent to those of ordinary skill in the art without departing from the scope and spirit of the described embodiments. The embodiment was chosen and described in order to best explain the principles of the invention, the practical application, and to enable others of ordinary skill in the art to understand the invention for various embodiments with various modifications as are suited to the particular use contemplated. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
receiving a product specification data structure comprising a specification of a product for manufacture;
processing the product specification data structure to extract features of the specification of the product;
processing the extracted features to identify a bill of materials (BOM) and a manufacturing process specification detailing a sequence of manufacturing operations to be performed using the BOM to manufacture the product;
executing a plurality of computer model simulations, by one or more machine learning trained artificial intelligence (AI) computer models, of the manufacturing process, based on the BOM and the manufacturing process specification, under a plurality of different arrangements of manufacturing equipment of an industrial floor;
selecting an optimal arrangement of the manufacturing equipment based on results of the execution of the plurality of computer model simulations; and
generating an output to at least one computing device to implement the selected optimal arrangement of manufacturing equipment on the industrial floor.

2. The method of claim 1, wherein the one or more machine learning trained AI computer models comprise a separate first AI computer model for each piece of manufacturing equipment of the industrial floor to simulate an operation of the piece of manufacturing equipment, and a second AI computer model for simulating the industrial floor as a whole.

3. The method of claim 1, wherein selecting an optimal arrangement of manufacturing equipment based on results of the execution of the plurality of computer model simulations comprises selecting an optimal arrangement that reduces a total cost of ownership of the manufacturing equipment of the industrial floor.

4. The method of claim 1, wherein generating an output comprises sending control signals to at least one of automated or robotic manufacturing equipment to automatically rearrange a position, orientation, or configuration of the automated or robotic manufacturing equipment based on the selected optimal arrangement.

5. The method of claim 1, further comprising:
automatically rearranging the manufacturing equipment of the industrial floor to match the selected optimal arrangement;
performing real-time monitoring of the manufacturing equipment using sensors associated with the manufacturing equipment or environment of the industrial floor after rearrangement to collect real-time data regarding performance of the manufacturing equipment; and
feeding the real-time data into the plurality of computer model simulations to update the computer model simulations.

6. The method of claim 1, further comprising:
identifying one or more non-value-added activities in the selected optimal arrangement of the manufacturing equipment;
identifying for the one or more non-value-added activities, alternative manufacturing equipment, upgrades of existing manufacturing equipment, or maintenance opportunities for the existing manufacturing equipment, which address inefficiencies associated with the one or more non-value-added activities; and
providing a recommendation output to an authorized personnel computing device based on the identified alternative manufacturing equipment, upgrades, or maintenance opportunities.

7. The method of claim 1, further comprising performing a cost-benefit analysis of the selected optimal arrangement with regard to costs associated with rearranging the manufacturing equipment of the industrial floor.

8. A computer program product comprising:
one or more computer-readable storage media; and
program instructions stored on the one or more computer-readable storage media to perform operations comprising:
receiving a product specification data structure comprising a specification of a product for manufacture;
processing the product specification data structure to extract features of the specification of the product;
processing the extracted features to identify a bill of materials (BOM) and a manufacturing process specification detailing a sequence of manufacturing operations to be performed using the BOM to manufacture the product;
executing a plurality of computer model simulations, by one or more machine learning trained artificial intelligence (AI) computer models, of the manufacturing process, based on the BOM and the manufacturing process specification, under a plurality of different arrangements of manufacturing equipment of an industrial floor;
selecting an optimal arrangement of the manufacturing equipment based on results of the execution of the plurality of computer model simulations; and
generating an output to at least one computing device to implement the selected optimal arrangement of manufacturing equipment on the industrial floor.

9. The computer program product of claim 8, wherein the one or more machine learning trained AI computer models comprise a separate first AI computer model for each piece of manufacturing equipment of the industrial floor to simulate an operation of the piece of manufacturing equipment, and a second AI computer model for simulating the industrial floor as a whole.

10. The computer program product of claim 8, wherein selecting an optimal arrangement of manufacturing equipment based on results of the execution of the plurality of computer model simulations comprises selecting an optimal arrangement that reduces a total cost of ownership of the manufacturing equipment of the industrial floor.

11. The computer program product of claim 8, wherein generating an output comprises sending control signals to at least one of automated or robotic manufacturing equipment to automatically rearrange a position, orientation, or configuration of the automated or robotic manufacturing equipment based on the selected optimal arrangement.

12. The computer program product of claim 8, wherein the operations further comprise:
automatically rearranging the manufacturing equipment of the industrial floor to match the selected optimal arrangement;
performing real-time monitoring of the manufacturing equipment using sensors associated with the manufacturing equipment or environment of the industrial floor after rearrangement to collect real-time data regarding performance of the manufacturing equipment; and
feeding the real-time data into the plurality of computer model simulations to update the computer model simulations.

13. The computer program product of claim 8, wherein the operations further comprise:
identifying one or more non-value-added activities in the selected optimal arrangement of the manufacturing equipment;
identifying for the one or more non-value-added activities, alternative manufacturing equipment, upgrades of existing manufacturing equipment, or maintenance opportunities for the existing manufacturing equipment, which address inefficiencies associated with the one or more non-value-added activities; and
providing a recommendation output to an authorized personnel computing device based on the identified alternative manufacturing equipment, upgrades, or maintenance opportunities.

14. The computer program product of claim 8, wherein the operations further comprise performing a cost-benefit analysis of the selected optimal arrangement with regard to costs associated with rearranging the manufacturing equipment of the industrial floor.

15. A computer system comprising:
a processor set;
one or more computer-readable storage media; and
program instructions stored on the one or more computer-readable storage media to cause the processor set to perform operations comprising:
receiving a product specification data structure comprising a specification of a product for manufacture;
processing the product specification data structure to extract features of the specification of the product;
processing the extracted features to identify a bill of materials (BOM) and a manufacturing process specification detailing a sequence of manufacturing operations to be performed using the BOM to manufacture the product;
executing a plurality of computer model simulations, by one or more machine learning trained artificial intelligence (AI) computer models, of the manufacturing process, based on the BOM and the manufacturing process specification, under a plurality of different arrangements of manufacturing equipment of an industrial floor;
selecting an optimal arrangement of the manufacturing equipment based on results of the execution of the plurality of computer model simulations; and
generating an output to at least one computing device to implement the selected optimal arrangement of manufacturing equipment on the industrial floor.

16. The computer system of claim 15, wherein the one or more machine learning trained AI computer models comprise a separate first AI computer model for each piece of manufacturing equipment of the industrial floor to simulate an operation of the piece of manufacturing equipment, and a second AI computer model for simulating the industrial floor as a whole.

17. The computer system of claim 15, wherein selecting an optimal arrangement of manufacturing equipment based on results of the execution of the plurality of computer model simulations comprises selecting an optimal arrangement that reduces a total cost of ownership of the manufacturing equipment of the industrial floor.

18. The computer system of claim 15, wherein generating an output comprises sending control signals to at least one of automated or robotic manufacturing equipment to automatically rearrange a position, orientation, or configuration of the automated or robotic manufacturing equipment based on the selected optimal arrangement.

19. The computer system of claim 15, wherein the operations further comprise:
automatically rearranging the manufacturing equipment of the industrial floor to match the selected optimal arrangement;
performing real-time monitoring of the manufacturing equipment using sensors associated with the manufacturing equipment or environment of the industrial floor after rearrangement to collect real-time data regarding performance of the manufacturing equipment; and
feeding the real-time data into the plurality of computer model simulations to update the computer model simulations.

20. The computer system of claim 15, wherein the operations further comprise:
identifying one or more non-value-added activities in the selected optimal arrangement of the manufacturing equipment;
identifying for the one or more non-value-added activities, alternative manufacturing equipment, upgrades of existing manufacturing equipment, or maintenance opportunities for the existing manufacturing equipment, which address inefficiencies associated with the one or more non-value-added activities; and
providing a recommendation output to an authorized personnel computing device based on the identified alternative manufacturing equipment, upgrades, or maintenance opportunities.
